(19) United States
(12) Patent Application Publication
(10) Pub. No.: US 2024/0202918 A1
(43) Pub. Date: Jun. 20, 2024

(54) LIGHT SOURCE FOR DETERING INTRAVENOUS DRUG USE IN PUBLIC SPACES

(71) Applicant: CURRENT LIGHTING SOLUTIONS, LLC, Beachwood, OH (US)

(72) Inventors: William Erwin COHEN, Solon, OH (US); William Winder BEERS, Chesterland, OH (US)

(21) Appl. No.: 18/536,785

(22) Filed: Dec. 12, 2023

Related U.S. Application Data
(60) Provisional application No. 63/433,129, filed on Dec. 16, 2022.

(51) Int. Cl. G06T 7/00; H01L 27/15

(52) U.S. Cl. CPC G06T 7/0012; H01L 27/15; G06T 2207/30101

(57) ABSTRACT

A composite lighting apparatus and methods for inhibiting the optical imaging of subcutaneous veins. In an embodiment, the lighting apparatus includes a first narrow light emitter and a second narrow light emitter. When the first narrow light emitter and the second narrow light emitter are energized then a composite light is emitted that is characterized by a cyanosis observation index (COI) value of greater than four (4.0) and has a correlated color temperature (CCT) of between about 2000° K to about 50,000° K that is one of on the blackbody locus or near the blackbody locus. In some implementations, the first narrow light emitter may emit a blueish light and may have a peak wavelength in the range of about four hundred forty nanometers (440 nm) to about four hundred and sixty nanometers (460 nm). In some other embodiments, the second narrow light emitter may emit a yellowish light and may have a peak wavelength in the range of about five hundred and sixty nanometers (560 nm) to about five hundred and eighty-five nanometers (585 nm).

### CROSS REFERENCE TO RELATED APPLICATION

This U.S. patent application claims the benefit of U.S. Provisional Patent Application No. 63/433,129 filed on Dec. 16, 2022, which application is incorporated herein by reference for all purposes.

### FIELD OF THE INVENTION

The present disclosure generally relates to a light source which may be used in public spaces, and which emits light that deters intravenous drug use. More specifically, in some embodiments provided is a light source that emits a modified blue light having a color point that is on or close to the black body locus and thus emits a good quality light which also minimizes and/or inhibits the ability of intravenous drug users to see or image veins beneath their skin.

### BACKGROUND

Medical practitioners are routinely required to locate a vein of a patient to take blood samples and/or to inject prescribed drugs and/or to provide a peripheral intravenous (I.V.) cannulation. Accordingly, nurses and/or doctors and/or other medical practitioners do their best in such situations to accurately locate an appropriate vein and then quickly insert a needle so that the patient can be made as comfortable as possible. Many different factors contribute to being able to easily locate a patient's vein, such as the experience of the nurse or other medical practitioner, the patient's skin thickness and the quality of light illuminating the patient.

It has been found that differences in optical, physical and biological properties explain why blood vessels can be seen when the skin is irradiated with visible light of an appropriate wavelength. Inside human tissues, light reflection, scattering and absorption play a role, and it has been found that scattering is the dominant factor affecting light propagation. Inside skin, keratin and melanin from the epidermis form the main scattering barrier, and in the dermis layer (where blood vessels are located) scattering is produced by heterogeneities derived from the variable cellular components presented in the different sublayers and by different molecular concentrations. But physical responses derived from a tissue after having been irradiated with an incident light beam not only depend on the tissue biological properties but also on the features of the light source. Factors such as the wavelength of the incident light, the optical power emitted by the light source and the exposure rate, the irradiated area, the irradiation time, the number of pulses and their duration and the polarization state will influence the tissue response. The exposure size of the light also affects the effective penetration depth, achieving a deeper penetration when the intensity given by the light source is greater. Thus, in medical applications, the properties of the light source should not be considered in isolation from the tissue properties of the patient and the physical optical phenomena. Accordingly, it has been found that light of an appropriate wavelength must be used to irradiate the skin to penetrate enough into the skin to reach blood vessels and be reflected again to the surface.

Vein finder tools are known in the medical field and typically include one or more Light Emitting Diodes (LEDs) that emit light which penetrates a patient's skin to aid a medical practitioner to locate veins. Researchers found that only light sources emitting light above a wavelength threshold of about 580 nm penetrated deep enough into the skin to reach blood vessels and make visualization possible. Thus, vein finders typically emit a red color light having a wavelength of about 620 nanometers (nm) which red light makes veins appear as a dark red or blackish color to the human eye.

Some researchers have also noted that that the use of pure indigo light sources in areas such as public restrooms may generally inhibit the injection of illicit drugs by intravenous drug abusers (or drug addicts) because such light sources emit light at wavelengths that cannot penetrate the epidermis layer of human skin, which makes it very difficult for the drug user to locate a vein. However, the use of such light sources, which emit a dark purplish blue light, could be taken by other members of the public as an indication that intravenous drug users frequent that restroom of that establishment (i.e., shop or convenience store). This could adversely affect the establishment if those customers decide to leave and/or not return. Thus, it would be desirable to have an illumination system or lamp capable of generating a generally white light that does not penetrate the epidermis layer and therefore deters drug addicts from injecting intravenous drugs.

Explained below are some concepts and medical terms which help explain how the light emitted by light sources is important when trying to locate a subcutaneous vein and/or assessing the condition of a patient. For example, the available lighting in a hospital or clinical setting plays a critical role in the accurate assessment of the visual appearance of a patient's skin, including the detection of cyanosis. Cyanosis is a blue coloration of the skin and mucous membranes due to the presence of deoxygenated hemoglobin in blood vessels near the skin surface. Lack of blood oxygenation is an indicator of many potentially harmful medical conditions, some of which may be fatal.

Fully oxygenated blood generally appears as a shade of red but when blood is deoxygenated the optical properties of skin distort the dark red color making the skin appear blueish. During cyanosis, tissues that would normally be filled with bright oxygenated blood are instead filled with darker, deoxygenated blood. The scattering of light that produces the blue hue is similar to the process that renders coloration in other objects. Specifically, certain wavelengths (colors) dominate the reflected spectrum while others are mostly absorbed. Darker blood absorbs more red wavelengths causing a blue-shifting optical effect, and thus oxygen deficiency leads to an observable blue discoloration of the lips and other mucous membranes. Accordingly, in order for cyanosis to be accurately detected, the lighting in hospital and/or clinical settings should be white, so that the coloration of skin detected by the observing caregiver is not influenced by lighting that inherently casts a dominant hue.

The Cyanosis Observation Index (COI) was developed to measure the suitability of lamps for cyanosis detection. The COI is an open-ended numerical scale ranking the suitability of a lamp for the purpose of visual detection of the presence or onset of cyanosis. The index is a dimensionless number, calculated from the spectral power distribution of a lamp, and is established by calculating the change in color appearance of fully oxygenated blood, i.e, 100% oxygen saturation, and of oxygen-reduced, cyanosed blood, as assessed by a test lamp, and as compared to a reference lamp. Lamps exhibiting lower index values are better suited for use in hospital and clinical evaluation settings for detecting the presence of cyanosis. The limiting value on the index is 3.3, with values greater than 3.3 being understood as unacceptable for use in clinical observation settings. Specifically, the standard requires the use of lamps meeting a COI of not more than 3.3 and having a Correlated Color Temperature (CCT) between 3300 degrees Kelvin (3330° K) and 5300° K.

Correlated Color Temperature (CCT) is a measure of the “shade” of whiteness of a light source by comparison to a blackbody in equilibrium at a specific temperature. The CCT of typical incandescent lighting is 2700° K which is yellowish-white, whereas Halogen lighting has a CCT of 3000° K. CCT can be calculated using the ccx, ccy coordinates of a light source as plotted on a CIE standard chromaticity diagram, as known to those skilled in the art.

The color rendering index (CRI) of a lamp is a measure of its effect on the color appearance of objects in comparison with their appearance under a standard source, such as daylight or a blackbody. Since the spectrum of incandescent lamps is very close to a standard blackbody, they have a CRI of 100. Fluorescent lamps achieve CRI ranging from about 50 to about 95, and some fluorescent lamps have low red-light emission, especially those with high CCT values. These lamps can make skin appear less pink, and hence “unhealthy” as compared to evaluation under incandescent lighting. Since the human eye is relatively less efficient at detecting red light, light sources with increased energy in the red part of the spectrum will have reduced overall luminous efficacy.

The COI standard discussed above is used as a guideline for lighting in hospitals and clinical observation areas where visual observation of a patient's condition is rendered. While some lamps that exhibit values acceptable for clinical settings are commercially available, few if any generate a spectrum whose COI is well below the 3.3 standard. One manner of optimizing lamp performance for the purpose of cyanosis detection is to optimize the combination of light sources employed in a lamp or illumination system to generate a spectrum of white light whose COI is less than 3.3 and preferably less than 2.0. As a result, commercially available lamps that exhibit a COI value higher than 3.3 are unsuitable for visual observation of a patient's condition.

Accordingly, for the purposes of deterring intravenous drug abusers (drug addicts) from locating veins in public areas, such as public restrooms or parking lots, it would be desirable to have an illumination system or lamp capable of generating light that achieves a COI value of more than 4.0. In addition, it would also be desirable for at least some embodiments of the illumination system to exhibit a CCT of between about 2500° K and 14000° K that is near or on the blackbody locus.

### BRIEF SUMMARY OF THE INVENTION

Presented are composite lighting apparatus and methods for inhibiting the optical imaging of subcutaneous veins. In an embodiment, the lighting apparatus includes a first narrow light emitter and a second narrow light emitter wherein when the first narrow light emitter and the second narrow light emitter are energized then a composite light is emitted that is characterized by a cyanosis observation index (COI) value of greater than four (4.0) and has a correlated color temperature (CCT) of between about 2000° K to about 50,000° K that is one of on the blackbody locus or near the blackbody locus. In some implementations, the first narrow light emitter may emit a blueish light and may have a peak wavelength in the range of about four hundred forty nanometers (440 nm) to about four hundred and sixty nanometers (460 nm). In some other embodiments, the second narrow light emitter may emit a yellowish light and may have a peak wavelength in the range of about five hundred and sixty nanometers (560 nm) to about five hundred and eighty-five nanometers (585 nm).

In some embodiments of the lighting apparatus, when the first and second narrow light emitters are energized the composite light that is emitted may be characterized by a COI value of greater than 20, and/or may be characterized by a COI in the range of about 21 to about 46. In addition, in some implementations at least one of the first and second narrow light-emitters may include a light-emitting diode (LED), an organic light-emitting diode (OLED), a fluorescent lamp, a vapor discharge lamp, or an HID lamp.

Also presented herein is a lamp which when energized inhibits the optical imaging of subcutaneous veins. In some embodiments the lamp includes at least two light-emitting elements having a combined light emission when energized, and when the at least two light-emitting elements are energized the lamp generates light exhibiting a correlated color temperature (CCT) of between about 2000 Kelvin (2000° K) to about 50,000° K, having a cyanosis observation index (COI) in the range of about 21 and 46, and having a CRI value of between about −13 and 41. In some implementations, at least one of the light-emitting elements may include a light-emitting diode (LED), an organic light-emitting diode (OLED), a fluorescent lamp, a vapor discharge lamp, or an HID lamp.

In yet another aspect, presented is a method for providing a lamp which when energized inhibits the optical imaging of subcutaneous veins. The method includes (a) identifying a target chromaticity point having a ccy value within +/−0.02 of the blackbody locus and having a (ccy, ccx) point lying within the CCT range of 2,000 degrees Kelvin (2,000° K) and 50,000° K; (b) identifying a target cyanosis observation index (COI) value greater than 4.0 desired for the lamp; (c) identifying a target CRI value desired for the lamp; (d) choosing a plurality, “n,” of light sources having distinct emissions (ccxᵢ, ccyᵢ), where i=2 to n, such that the color triangle formed by at least one set of three (ccxᵢ, ccyᵢ) values contains the target chromaticity point or for that scenario where only two light sources having distinct emission are chosen, a line connecting their (ccxᵢ, ccyᵢ) values that includes the target (ccx, ccy); (e) combining the light sources from step (d) in a ratio such that the target (ccx, ccy) value is obtained; (f) calculating the COI using the AS/NZS 1680 standard; (g) calculating the CCT from the ccx, ccy coordinates of the combined light sources from (d); (h) calculating the CRI of the system; (i) comparing the calculated COI to the target COI from step (b); (j) comparing the calculated CRI to the target CRI from (c); and (k) if the target values are not achieved, returning to step (d) and choosing additional or replacement light sources that satisfy the condition of step (d) and repeating steps (e)-(j) until the targets are met, or, if the target values are achieved, (l) constructing and measuring the illumination system to ensure compliance with the target values established in steps (a)-(c). In some embodiments of the method the selected COI value of the lamp may be in the range of about 21 to about 46, and the selected CRI value of the lamp may be in the range of about of about −13 and 41. In addition, at least one of the at least two light sources may include a light-emitting diode (LED), an organic light-emitting diode (OLED), a fluorescent lamp, a vapor discharge lamp, or an HID lamp.

### BRIEF DESCRIPTION OF THE DRAWINGS

Features and advantages of some embodiments, and the manner in which the same are accomplished, will become more readily apparent with reference to the following detailed description taken in conjunction with the accompanying drawings, which illustrate exemplary embodiments (not necessarily drawn to scale), wherein:

FIG. 1 is a table illustrating different combinations of LED emitters for providing a light source exhibiting a CCT of between about 2500° K to about 14,000° K, and a COI of greater than 4.0 in accordance with this disclosure.

FIG. 2 is a table including three examples of “pure blue” light emitters in accordance with some embodiments of the disclosure.

FIG. 3 depicts a table illustrating several different combinations of light emitters for providing a light source that emits light on the blackbody locus exhibiting a very high CCT value of about 50,000° K and a COI of about 45 to 46 in accordance with some embodiments of the disclosure.

FIG. 4 is a flowchart illustrating a method for designing a light system that includes at least two solid-state light-emitting light sources in accordance with the disclosure.

FIG. 5 is a table of example calculations for providing suitable light sources that combine two or more LEDs using the process described in the flowchart of FIG. 4 in accordance with some embodiments of the disclosure.

### DETAILED DESCRIPTION

Reference now will be made in detail to illustrative embodiments, one or more examples of which are illustrated in the drawings which may or may not be drawn to scale. Like components and/or items in the various drawings are identified by the same reference number, and each example is provided by way of explanation only and thus does not limit the invention. In fact, it will be apparent to those skilled in the art that various modifications and/or variations can be made without departing from the scope and/or spirit of the invention. For example, in many cases features illustrated or described as part of one embodiment can be used with another embodiment to yield a further embodiment. Thus, it is intended that the present disclosure covers such modifications and variations as come within the scope of the appended claims and their equivalents.

As used herein, approximating language may be applied to modify any quantitative representation that may vary without resulting in a change in the basic function to which it is related. Accordingly, a value modified by a term or terms, such as “about” and “approximately” and “substantially,” may not be limited to the precise value specified. The modifiers “about,” “approximately” and “substantially” used in connection with a quantity are inclusive of the stated value and have the meaning dictated by the context (for example, includes the degree of error associated with the measurement of the particular quantity). “Optional” or “optionally” means that the subsequently described event or circumstance may or may not occur, or that the subsequently identified material may or may not be present, and that the description includes instances where the event or circumstance occurs or where the material is present, and instances where the event or circumstance does not occur or the material is not present. The singular forms “a”, “an” and “the” include plural referents unless the context clearly dictates otherwise. All ranges disclosed herein are inclusive of the recited endpoint(s) and independently combinable. Also, as used herein, the phrases “adapted to,” “configured to,” and the like refer to elements that are sized, arranged and/or manufactured to form a specified structure or to achieve a specified result. In addition, as used herein the term “public area” refers to any area, whether inside a commercial establishment or inside another other facility or in an outdoor environment, where intravenous drug abusers (drug addicts) may go to inject illegal drugs into their veins.

In general, and for the purpose of introducing concepts of embodiments of the present invention, disclosed are light source embodiments that minimize, lessen and/or inhibit the ability of persons (such as intravenous drug users) to see or image veins underneath their skin (subcutaneous veins), while at the same time providing an acceptable light source color point. In some embodiments, such a light source is composed of a modified blue light emitter having a color point that is on (or close) to the black body locus in combination with a yellowish light emitter. For example, in an embodiment the light source may contain a blue light emitter that emits light with a wavelength of approximately 450 nanometers (nm), such as a Nichia™ cyan chip, in combination with a yellowish light emitter that emits light with a wavelength of about 560 nm.

Color is observed as a result of the reflection of light from objects. For example, an object appears blue because it absorbs all of the non-blue light and reflects blue light back to the eyes of the viewer. Therefore, a light source having an absence of any specific color will not detect that color and the human eye will not perceive that color as being illuminated. When applying this principle to preventing the detection of a vein under human skin it is important to be sure that the light source includes emittance in the blue portion of the visible spectrum because the color of blood is naturally red (which is the portion of the spectrum that lies at about 660 nm). Thus, some embodiments of a light source in accordance with this disclosure include a first blueish emitter having a wavelength peak of about 440 nm to about 460 nm and a second yellowish emitter having a wavelength peak of about 560 nm to about 585 nm.

In embodiments of a light source that minimizes or inhibits the ability of an intravenous drug abuser to see subcutaneous veins, the spectral fraction of the blueish emitter must be matched with an appropriate spectral fraction of the yellowish emitter to enable a color point that is on or near the black body locus. Thus, disclosed herein below is a method for determining how to combine the blue spectral fraction(s) of the blueish emitter with the yellow spectral fraction(s) of the yellowish emitter to achieve a light source having a perceived white light that also inhibits viewing of subcutaneous veins. In some embodiments of such a light source, a blueish emitter that emits light having a wavelength of about 450 nm is combined with an acceptable or targeted yellowish emitter that emits light of a wavelength of about 560 nm having a peak emission deviation no larger than about 5 nm. It should be understood, however, that the peak emission deviation of such a yellowish emitter may be different depending on what is the targeted correlated color temperature (CCT) of the light source. In addition, embodiments of the light source emit white light that exhibits a Cyanosis Observation Index (COI) of significantly more than 4.0, and in some embodiments that may also exhibit a CRI value of significantly less than about 70, and in some cases less than 28. Moreover, in some implementations when the illumination system is energized, the correlated color temperature (CCT) of the light is in the range of between about 2000° K and to about 50,000° K.

In some embodiments, the light system includes a plurality of solid-state light-emitting elements (two or more), such as light emitting diodes (LEDs) wherein at least two of the plurality of solid-state light-emitting elements have different color emission bands. The system is configured such that when it is energized, it provides a good quality light that appears white to the human eye. The terms “illumination system”, “lighting system” and “lamp” may be utilized substantially interchangeably herein to refer to any source of visible light that generates that visible light by blending the emissions from at least two solid-state light-emitting elements. In addition, the terms “solid-state light-emitting element” and “light source” may be utilized substantially interchangeably, and typically include any inorganic light emitting diode such as an LED, any organic light emitting diode (OLED), any inorganic electroluminescent device, laser diode, a quantum dot light source (i.e., semiconductor nanocrystals), and any combinations thereof, or the like. Furthermore, the terms “element” or “source” may include a coating, phosphor, filter or other modification that may be present in or on such element or source.

The term “solid state” commonly refers to light emitted by solid-state electroluminescence, as opposed to devices such as incandescent lamps (which use thermal radiation) or fluorescent and/or high intensity discharge lamps (which use a gaseous discharge). In broad outline, solid-state light emitting elements such as LEDs emit light from a solid, often a semiconductor, rather than from a metal or gas (as is the case in traditional incandescent lamps, fluorescent lamps, and other discharge lamps). Unlike traditional lighting sources, solid-state light emitting elements such as LEDs typically create visible light with less heat and less energy dissipation. In addition, the solid-state nature provides for greater resistance to shock, vibration and wear, thereby increasing the device durability significantly. Of more importance herein, however, is the capability to tailor the spectra of an illumination system by using solid-state light-emitting elements due to the better-defined peak wavelength, or color spectrum, of solid-state light-emitters. Even though incandescent and fluorescent sources are not generally categorized as “solid-state” in the industry, to some degree they are solid-state given that in conventional fluorescent lamps most light is generated in the solid-state fluorescent phosphor coating of the tube, and in conventional incandescent lamps light is generated in the solid-state tungsten filament.

In embodiments, the light source includes two or more light emitting diodes (LEDs). An LED may be defined as a solid-state semiconductor device that converts electrical energy directly into light. The output of an LED is a function of its physical construction, the materials used, and the exciting current. In addition, the output may be in the ultraviolet, the visible, or in the infrared regions of the spectrum. The wavelength of the emitted light is determined by the band gap of the materials in the p-n junction and is usually characterized as having a peak (or dominant) wavelength, λₚ, at which the emission is maximum, and a distribution of wavelengths, encompassing the peak wavelength, over which the emission is substantial. The distribution of wavelengths is typically characterized by a Gaussian probability density function.

Perceived color is principally determined by the LED peak wavelength, λₚ, even though the distribution is not monochromatic, but rather exhibits a “color band”, which refers to a finite spread in wavelengths of a few times in the range of about 5 nm to 50 nm. The entire wavelength range over which the LED emits perceivable light is substantially more narrow than that of the entire range of visible light, which generally encompasses from about 390 nm to about 750 nm, so that each LED is perceived as a specific non-white color. In addition, individual LED devices that are nominally rated to have the same peak wavelength typically exhibit a range of peak wavelengths due to manufacturing variability. LED devices may be grouped into color bins that limit the peak wavelength to a range of allowable peak wavelengths encompassing the intended peak wavelength. A typical range of peak wavelengths defining the limits of a color bin for colored LED devices is about 5 nm to 50 nm.

Because LED lamps comprise LED devices of many different color bands and individual colors, this type of light source offers many more choices from which to select those light sources (LEDs) that will be included in the illumination system in accordance with this disclosure. By careful selection of the light sources used in an illumination system, for example by selecting specific LED devices, a combination of peak wavelengths can be created to generate a lamp spectrum with a COI well above 4.0, and even well above 20.0. Accordingly, in embodiments disclosed herein the light source has the following two attributes: first, a color point that is on or near the black body locus; and second, a cyanosis observation index (COI) that is much greater than 3.3, and preferably above 20.0, and more preferably in the range from about 42 to about 48. In addition, in implementations disclosed herein the light source has little ultraviolet (UV) content to minimize any change of fluorescence of molecules in human veins or in human skin. A lamp having these features and exhibiting a CCT in the range of between about 2000° K to about 50,000° K provides an illumination system that minimizes or inhibits the ability of intravenous drug users to see veins underneath their skin, while at the same time providing an acceptable light source color point.

In some embodiments, one or both of the emitters of the light source can be a narrow emitting light-emitting diode (LED) or a narrow emitting phosphor. Thus, in some embodiments a 450 nm emitter in the form of an LED-based chip is used along with a 560 nm narrow emitting LED. In another implementation the 560 nm emitter is a narrow emitting phosphor.

In another embodiment, the light source may include one or more organic light-emitting diodes (OLED) devices. An OLED device typically includes one or more organic light emitting layers disposed between electrodes (e.g., a cathode and a light transmissive anode) formed on a substrate (which may be a light-transmissive substrate), wherein the layers together form an “organic electroluminescent element”. The light-emitting layer emits light upon application of a current across the anode and cathode. Upon the application of an electric current, electrons may be injected into the organic layer from the cathode, and holes may be injected into the organic layer from the anode. The electrons and the holes generally travel through the organic layer until they recombine at an electroluminescent center, typically an organic molecule or polymer, resulting in the emission of a light photon, usually in the ultraviolet or visible regions of the spectrum. Therefore, as used herein, the term “organic electroluminescent element” or “OLED” generally refers to a device (e.g., including electrodes and active layers) comprising an active layer or layers having an organic material (molecule or polymer) that exhibits the characteristic of electroluminescence. The chemical composition of the organic electroluminescent material determines the “band gap” and the corresponding distribution of wavelengths of the emitted light from the luminescent center. Similar to the color band that characterizes the perceived color of an LED, the distribution of wavelengths emitted from an organic electroluminescent layer also produces a color band. However, unlike the case of the typically Gaussian shaped distribution of the LED color band, the color band of the organic electroluminescent element may have multiple peak wavelengths, and possibly a broader spectral width. Nonetheless, each luminescent center within an organic electroluminescent layer may be characterized by a perceived color that, having a finite distribution of wavelengths narrower than that of the entire range of visible light, may be referred to as a color band. There may be one or more different compositions of luminescent centers within each organic light-emitting layer so that each light-emitting layer may emit light in one or more color bands.

Because the color band of an OLED is generally less defined than that of an LED, there are fewer individual, distinct colored OLED devices available for combination in a light source, as compared to the number of LED devices available for combination. In fact, the emission spectra of an OLED may be even broader than that of fluorescent lamps. For this reason, OLED devices are generally less optimum light sources for use herein because the emission spectra of this type of source offers fewer individual colors to choose from to create the desired combination of spectral fractions needed to create a white light having the desired CCT and COI. Nonetheless, by careful selection of the light sources used in an illumination system, for example by selecting specific OLED devices, in accord with the method provided herein, a combination of peak wavelengths may be created to generate a spectrum whose COI is well above 4.0, and preferably well above 20, and more preferably in the range of 42-48.

While the primary focus of this disclosure is based on the use of solid-state emitters, it is to be understood that other known light sources may be selected using the calculation method provided herein. For example, a fluorescent light source which, as compared to LED sources, generally exhibits a broader color band having less defined peak wavelengths and including more of the spectrum in each, could be used. Although fluorescent sources offer fewer individual colors to choose from when combining colors to create the perceived white light having the desired CCT and COI, in accordance with the foregoing discussion regarding OLED light sources, by careful selection of the light sources used in an illumination system, for example by selecting specific fluorescent light sources, a combination of peak wavelengths can be created to generate an overall spectrum whose COI is well above 4.0 standard, and preferably well above 20, and more preferably in the range of 42-48. Similarly, high intensity discharge (HID) lamps may be employed, though they represent the most difficult to optimize for purposes disclosed herein.

In light of the foregoing, it should be understood that the calculation technique defined herein is equally applicable to any type of light source and will allow one to choose a combination of light sources that will generate light having a perceived white color and exhibiting a CCT of between about 2000° K to about 50,000° K and a COI of well over 4.0, and preferably more than 20, and most preferably in the range of about 42 to about 48, regardless of whether the light source is a solid-state light-emitting element or one that emits light from a metal material or gas discharge, such as are used in incandescent, high intensity or fluorescent lamps. Therefore, use of the term “solid-state light emitting element” or any part thereof is also applicable to other types of illumination systems as defined or suggested above.

In some embodiments, the illumination system may include two or more solid-state light emitting elements, and they may be arranged in a stacked or overlaid configuration, or in tandem. In some other embodiments, an illumination system includes at least one photoluminescent material (typically selected from, but not limited to, a phosphor, a quantum dot, and combinations thereof), for converting light from at least one of the solid-state light emitting elements to a different wavelength. Further embodiments of an illumination system may include at least one filter for modifying the total light of the illumination system. Suitable filters may possibly include materials which depress certain regions of the spectrum of the total light of the illumination system, such as neodymium-containing glass filters.

In embodiments of illumination systems according to the disclosure, an illumination system will exhibit a CCT of between about 2000° K to about 50,000° K and have a COI of much greater than 4.0, and preferably greater than 20, and more preferably within a range of about 42 to 48. The color appearance of an illumination system, per se (as opposed to objects illuminated by such illumination system) is described by its chromaticity coordinates or color point, which, as would be understood by those skilled in the art, can be calculated from its spectral power distribution according to standard methods. The locus of blackbody chromaticities on a ccx, ccy-diagram is known as the Planckian locus, and since light sources with equal CCT may lie significantly above or below the Planckian locus and provide undesirable non-white illumination, in addition to specifying CCT, it is necessary to specify ccx, ccy chromaticity points near the blackbody locus to obtain near white illumination.

According to some embodiments, there is provided an illumination system which provides a total light comprising a combination of solid-state light emitters, for example LED devices, having specified peak wavelengths that together generate a spectrum of emitted light which has a chromaticity point near or on the blackbody locus and that provides white light with a CCT of between about 2000° K to about 50,000° K and a COI of much greater than 4.0, preferably greater than 20, and more preferably within the range of between about 42 and 48. Illumination systems meeting these parameters provide light that is useful in illuminating an environment but that blocks or inhibits the ability of intravenous drug users to see subcutaneous veins.

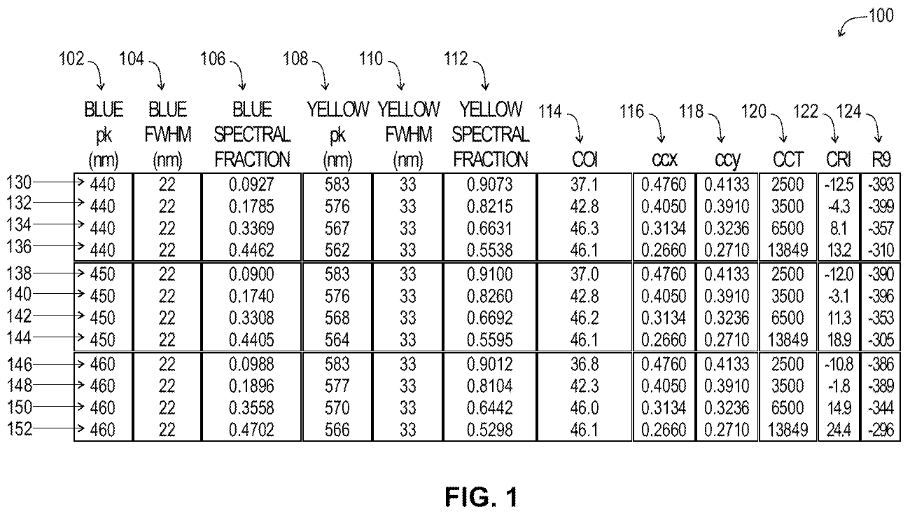

FIG. 1 is a table 100 illustrating different example combinations of LED emitters for providing a light source exhibiting a CCT of between about 2500° K to about 14,000° K, and a COI of much greater than 4.0 in accordance with this disclosure. A color temperature for the composite light source of 3500° K is known as “warm white” which is a reasonable color for a commercial lamp. The table 100 shown in FIG. 1 includes entries in column 102 for blueish emitters having Blue peak wavelengths of 440 nm (see rows 130, 132, 134 and 136), 450 nm (sec rows 138, 140, 142 and 144), and 460 nm (see rows 146, 148, 150 and 152), respectively. Column 104 lists the associated Blue FWHM (Full Width at Half Maximum) values, and column 106 lists the associated Blue Spectral Fractions. The table also includes entries in column 108 for yellowish emitters having Yellow Peak wavelengths ranging from 562 nm to 577 nm, column 110 listing the associated Yellow FWHM (Full Width at Half Maximum) values, and column 112 listing the associated Yellow Spectral Fractions. Column 114 includes the resultant COI for twelve different light sources, which are combinations of the blueish emitters and yellowish emitters illustrated in each row of the table 100. The values illustrate that blueish and yellowish emitters can be combined to attain a composite light source that has good color rendering and that emits light which inhibits imaging or viewing of subcutaneous veins.

FIG. 1 also includes column 116 containing ccx values and column 118 containing ccy values, which define the color point or the CCT values shown in column 120 which are on the blackbody locus (or the Planckian locus). In addition, the table 100 includes column 122 of associated CRI values, and column 124 of associated R9 values for each of the light sources. The CRI values equate to general color rendering, and the R9 values are specific to the color red. It has been found that varying the FWHM (Full Width Half Maximum) value affects the CRI and R9 values, and thus it is desirable to provide a high CRI for “natural light” and a relatively low R9 value because we are trying to avoid good red color emission. Thus, it is also desirable to balance the COI and CRI values. In particular, it is generally desirable to balance the desire for providing a light source having a good CRI value with the necessity for a high COI value.

Referring again to FIG. 1, rows 130-136 each correspond to a light source that incorporates a blueish emitter having a Blue Peak of 440 nm, while rows 138-144 each correspond to a light source that incorporates a blueish emitter having a Blue Peak of 450 nm, and rows 146-152 each correspond to a light source that incorporates a blueish emitter having a Blue Peak of 460 nm. Each blueish emitter has a different Blue Spectral Fraction in the range of about 0.0900 (or about 9%) to about 0.4700 (or about 47%; see column 106). In addition, each light source for each of these rows also incorporates a yellowish emitter having Yellow Peak wavelengths in the range of about 562 nm to 583 nm (see column 108) and Yellow Spectral Fraction values in the range of about 0.5300 (or about 53%) to about 0.9100 (or about 91%; see column 112). The resultant light sources, which include blueish and yellowish emitters, having a COI in the range of about 37 to about 46 (see column 114) and a CCT ranging from about 2500° K to about 14000° K (see column 120). The light emitted from such a light system, which may be composed of a “blue” LED in combination with “yellow” LED, is a good quality light that can be used indoors or outdoors but that inhibits the imaging of veins underneath human skin.

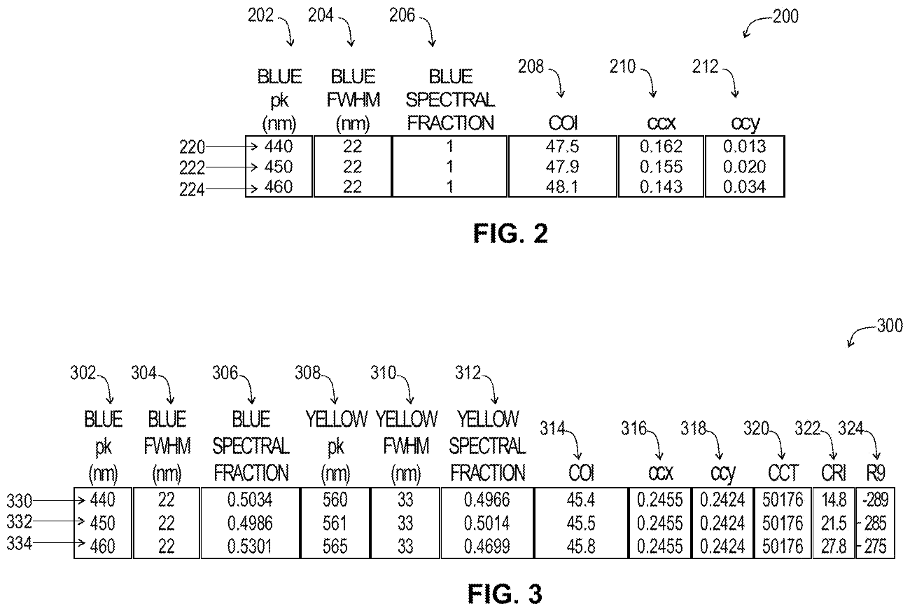

FIG. 2 depicts a table 200 including values for three “pure blue” light emitters shown in rows 220, 222 and 224. In particular, the blue light emitters have a Blue peak wavelength of 440 nm (row 220), 450 nm (row 222) and 460 nm (row 224). Column 204 lists the blueish emitters Blue FWHM (Full Width at Half Maximum) values, which are all 22, and column 206 lists the associated Blue Spectral Fractions which are all equal to 1. Each of the blueish emitters has a COI value of between about 47 to about 48 (see column 208), a ccx value of about 0.143 to 0.162 (see column 210) and a ccy value of about 0.010 to 0.035 (see column 212) which define the color point. Such pure blue light emitters may be used in combination with a yellowish emitter to form a light system which inhibits the imaging of subcutaneous veins as disclosed herein.

FIG. 3 depicts a table 300 illustrating several different combinations of light emitters for providing a light source that emits light on the blackbody locus exhibiting a very high CCT value of about 50,000° K and a COI of about 45 to 46 in accordance with this disclosure. Referring to FIG. 3, the table 300 includes entries in column 302 for blueish emitters having Blue peak wavelengths of 440 nm (see row 330), 450 nm (see row 332) and 460 nm (sec row 334). Column 304 lists the associated Blue FWHM (Full Width at Half Maximum) values, which are 22 for all three emitters, and column 306 lists the associated Blue Spectral Fractions which are in the range of about 0.5000 to about 0.5300 (or about 50% to 53%). The table 300 also includes entries in column 308 for yellowish emitters having Yellow Peak wavelengths ranging from about 560 nm to 565 nm, column 310 lists the associated Yellow FWHM (Full Width at Half Maximum) values which are all 33, and column 312 lists the associated Yellow Spectral Fractions which range from about 0.4700 to 0.5000 (or about 47% to 50%). Column 314 lists the resultant COI values for the three combinations of blueish and yellowish emitters which are in the range of about 45.4 to about 45.8 (see rows 330, 332 and 334). In addition, each combination of blueish and yellowish emitters provides a very high CCT value of about 51,000 (see column 320), a CRI value in the range of about 15 to about 28, and R9 values in the range of about −289 to about −275. Columns column 316 and 318 contain ccx and ccy values, respectively, used to calculate the CCT values shown in column 320 which are on the blackbody locus (or the Planckian locus). Accordingly, the values in the table of FIG. 3 illustrate that blueish and yellowish emitters can be combined to attain a composite light source that has good color rendering and that emits light which inhibits imaging or viewing of subcutaneous veins.

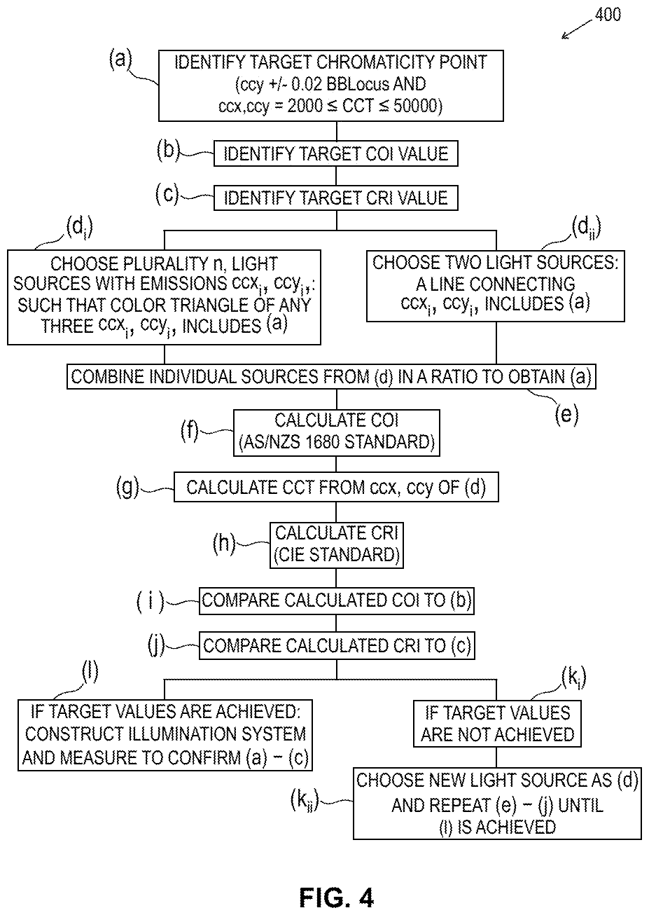

FIG. 4 is a flowchart 400 which illustrates a method for designing a light system that includes at least two solid-state light-emitting light sources in accordance with the disclosure. In particular, the method shown in FIG. 4 provides a light source having at least two solid-state light-emitting elements that emit a white light with a CCT of between about 2000° K to about 50,000° K and a COI of much greater than 4.0.

Referring to FIG. 4, the method includes: (a) identifying a target chromaticity point having a ccy value within +/−0.02 of the blackbody locus and having a (ccx, ccy) point lying within the CCT range of about 2000° K to about 50,000° K; (b) identifying a target COI value desired for the lighting system that is much greater than 4, and in some embodiments in the range of about 37 to about 48; (c) identifying a target CRI value desired for the lighting system in the range of about −12 to about 24; (d) choosing a plurality, “n,” of light sources having distinct emissions (ccxᵢ, ccyᵢ), where i=2 to n, such that the color triangle formed by at least one set of three (ccxᵢ, ccyᵢ) values contains the target chromaticity point or for that scenario where only two light sources having distinct emission are chosen, a line connecting their (ccxᵢ, ccyᵢ) values that includes the target (ccx, ccy); (e) combining the light sources from (d) in a ratio such that the target (ccx, ccy) value is obtained; (f) calculating the COI using the AS/NZS 1680 standard; (g) calculating the CCT from the ccx, ccy coordinates of the combined light sources from (d); (h) calculating the CRI of the system; (i) comparing the calculated COI to the target COI from (b); (j) comparing the calculated CRI to the target CRI from (c); and (k) if the target values are not achieved, returning to step (d) and choosing additional or replacement light sources that satisfy the condition of step (d) and repeating steps (e)-(j) until the targets are met, or, if the target values are achieved, (l) constructing and measuring the illumination system to ensure compliance with the target values established in steps (a)-(c).

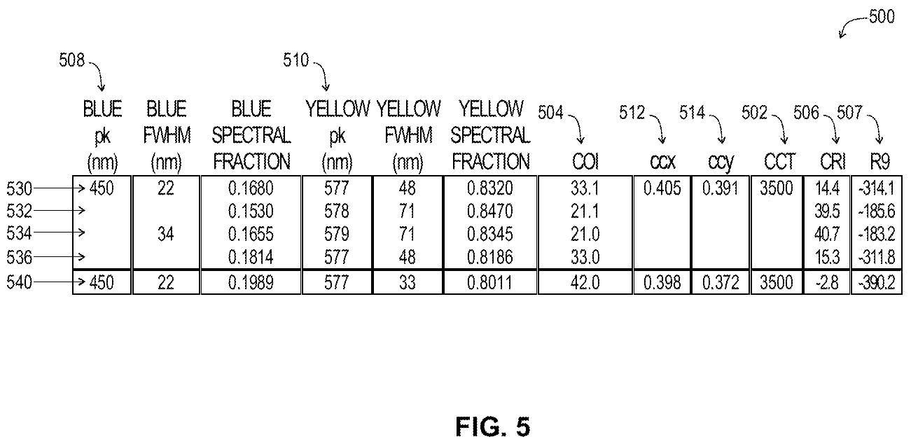

FIG. 5 is a table 500 of example calculations for providing suitable light sources that combine two or more LEDs using the process described in the flowchart 400 of FIG. 4 in accordance with the disclosure. Specifically, the table 500 concerns using two LEDs, a blueish LED 508 having a blue peak of 450 nm and a yellowish LED 510 having a yellow peak between 577 nm and 579 nm. The example light sources illustrated by rows 530, 532, 534 and 536 in table 500 have different FWHM values for the yellowish LEDs than those shown in the table 100 of FIG. 1, but the various combinations of blueish and yellowish LEDs result in the same ccx, ccy value and thus a CCT value of 3500. Specifically, regarding the light source defined by row 530, in accordance with the method of FIG. 4 a target chromaticity point of 3500 was chosen (which is between 2000 and 50,000), as was a target COI value of 33 and a target CRI value of about 14. Next, the two light sources were combined in a ratio to obtain the CCT of about 3500° K, and a COI was calculated using the AS/NZS 1680 Standard (which in this example is equal to 33.1). The CRI was also calculated using the CIE Standard. Next, the calculated values of COI and CRI are compared to the target COI and CRI values, and if the target values are achieved then an illumination system is constructed and then measured to confirm that each of the target chromicity value, target COI value and the target CRI value are all satisfied. It should also be noted that row 540 illustrates a light source that has a color point (CRI) that is off the blackbody locus yet still provides light having a CCT value of 3500. Column 507 shows the associated R9 values for each of the light sources.

In accordance with some embodiments of the invention, a plurality of solid-state light-emitting elements in the illumination system are arranged in a grid, close packed, or other regular pattern or configuration. Non-limiting examples of such a regular pattern include grids in a hexagonal, rhombic, rectangular, square, or parallelogram configuration, or a regular spacing around the perimeter or the interior of a circle, square, or other multi-sided plane geometric shape, for example. For optimized color mixing, it may sometimes be desirable to keep the incidence of light-emitting elements of the same color being located adjacent to one another to a minimum. However, it may not always be possible to avoid same-color adjacency. Such light system construction is known to those skilled in the art and is not a limiting factor.

It will be appreciated that the number of solid-state light-emitting elements may be dependent on the light intensity of the elements as well as their peak wavelengths and distribution of wavelengths. Accordingly, any light system disclosed herein is not limited in the number of solid-state light-emitting elements (such as LEDs and/or OLEDs) that could be used to build a desired combined spectrum of light. Thus, a light system may include the use of solid-state light-emitting elements having at least two different color bands, i.e., solid-state light emitting elements emitting violet, blue, cyan, amber, yellow and/or orange, or other intermediate or mixtures of color bands may be included.

The illumination system in accordance with disclosed embodiments further includes a substrate for supporting the plurality of solid-state light-emitting elements. In general, such substrate may comprise a heat dissipating material capable of dissipating heat from the system. The general purpose for such substrate includes providing mechanical support and/or thermal management and/or electrical management and/or optical management for the plurality of solid-state light-emitting elements. Substrates can comprise one or more of a metal, a semiconductor, a glass, a plastic and/or a ceramic material, or any other suitable material or composite material. A printed circuit board or PCB is one specific example of a substrate. Other suitable substrates include various hybrid ceramics substrates and porcelain enamel metal substrates. Furthermore, one can render a substrate to be light reflecting, for example, by applying white masking on the substrate. In some cases, the substrate can be mounted in a base, and an example of a suitable base includes the well-known Edison screw base.

In embodiments of the invention, the illumination system will further include leads for providing electric current to at least one of the plurality of solid-state light emitting elements. The leads may be a portion of an electrical circuit because, as is generally known illumination devices and/or light systems have a plurality of solid-state light-emitting elements (such as LED devices of different colors) which may be controlled in both intensity and color by appropriate application of electrical current. Thus, one skilled in this field would broadly understand the electrical circuitry needed to provide power to solid-state light-emitting elements and the light sources disclosed herein are not intended to be limited to a particular circuit, but rather by characteristics of the total light of the illumination system.

In some embodiments, the illumination system may further include at least one controller and at least one processor, wherein the processor may be configured to receive signals from a controller to control the intensity of one or more of the solid-state light-emitting elements. Such a processor can include one or more microprocessors, microcontrollers, programmable digital signal processors, integrated circuits, computer software, computer hardware, electrical circuits, programmable logic devices, programmable gate arrays, and the like. In implementations, the controller is in communication with one or more sensors receptive to one or both of the total light emission (that is, the total light of the illumination system), and/or the temperature of the solid-state light-emitting elements. A sensor can be, for example, a photodiode or a thermocouple. The processor may in turn control (directly or indirectly) electric current to the solid-state light-emitting elements. In some embodiments, the light system can further include a user interface coupled to the controller to facilitate adjustment of the total light emission or the spectral content of the emitted light by a user.

According to some embodiments, the illumination system can comprise an envelope to at least partially enclose the plurality of solid-state light-emitting elements. Such an envelope may be substantially transparent or translucent in the direction of the intended light output, and the envelope may be constructed of one or more of plastic, ceramic, metal, composites, light-transmissive coatings, glass and/or quartz. In addition, the envelope can have be bulb-shaped, dome-shaped, hemispherical, spherical, cylindrical, parabolic, elliptical, flat, helical, or any other shape suitable for the purpose of protecting the components of the solid-state light-emitting elements and for permitting light emission therethrough.

The illumination system may include an optical facility that performs a light-affecting operation upon the light emitted by one or more of the solid-state light-emitting elements. As used herein, the term “optical facility” includes any one or more elements that can be configured to perform at least one light-affecting operation. Such a light affecting operation may include, but is not limited to, one or more of mixing, scattering, attenuating, guiding, extracting, controlling, reflecting, refracting, diffracting, polarizing, and beam-shaping. In other words, an optical facility has broad meaning sufficient to include a wide variety of elements that affect light. These light-affecting operations offered by the optical facility can be helpful in effectively combining the light from each of the plurality of solid-state light-emitting elements of the light system, so that the total light appears white, and preferably homogeneous in color appearance as well. Operations such as mixing and scattering are especially effective to achieve homogeneous white light. Operations such as guiding, extracting, and controlling are intended to refer to light-affecting operations that extract the light from the light-emitting elements, for maximizing luminous efficiency. These operations may have other effects as well. It is understood that there is possible overlap between the terms describing the light-affecting operation (e.g., “controlling” may include “reflecting”), but a person skilled in the art would understand the terms used.

In some implementations, the light system may include a scattering element or optical diffuser to mix light from two or more solid-state light-emitting elements. Typically, such scattering element or optical diffuser is selected from at least one of film, particle, diffuser, prism, mixing plate, or other color-mixing light guide or optic, or the like. A scattering element (e.g., an optical diffuser) may assist in obscuring individual RGB (red, blue, green, or other color) structure of different-colored solid-state light emitting elements, so that the color of the light source and the illumination upon a surface appears substantially spatially uniform in apparent color to the viewer.

In some embodiments, the optical facility can include a light guiding or shaping element such as a lens, a filter, an iris, a collimator, and the like. Alternatively, the optical facility can include an encapsulant for one or more of the solid-state light-emitting elements that are configured to mix, scatter or diffuse light. In another implementation, the optical facility includes a reflector or some other kind of light-extracting element(s) (for example, photonic crystals or waveguide).

As noted, according to some embodiments of the invention, one may employ a material that encapsulates individual solid-state light emitting elements (e.g., LED chips) to scatter or diffuse light, or to make homogeneous light. Usually, such an encapsulating material is substantially transparent or translucent. The encapsulating medium may, in some instances, be composed of a vitreous substance or a polymeric material such as epoxy, silicone, acrylates and the like. Such an encapsulating material may typically also include particles that scatter or diffuse light, which can assist in mixing light from different solid-state lighting elements. Particles which scatter or diffuse light can be any appropriate size and shape, as would be understood by those skilled in the art, and can be composed of, for example, an inorganic material such as silicon oxide, silicon, titania, alumina, indium oxide, tin oxide, or other metal oxides, and the like. In some embodiments, other types of diffusers and mixers may be used to diffuse light, or to make homogeneously colored light. They could be engineered diffuser films, for example, such as those used within the liquid crystal display (LCD) industry, that are prism films on various polymeric materials. In addition, it is also possible to guide and/or shape the LED light using different other optical components to further optimize color mixing within this light source. Suitable optical components include, for example, various lenses (concave, convex, planar, “bubble”, Fresnel and the like) and various filters (polarizers, color filters, etc.).

While examples have been presented herein utilizing LED light-emitting elements, one of skill can build or adapt a lamp system from a combination of LED devices and/or OLED devices and/or other solid-state light-emitting elements that meet the emission requirements noted herein when blended. Accordingly, one of skill would choose light emitting elements which match the spectra of the LED devices used in the novel combination(s) as disclosed. It is surprising that the proper selection of solid-state light-emitting elements and blending of their output will provide spectra that will inhibit imaging subcutaneous veins while at the same time providing adequate white light to illuminate a public space.

It should be understood that the above descriptions and/or the accompanying drawings are not meant to imply a fixed order or fixed sequence of steps for any process or processes and/or any apparatus and/or any system and/or any method of manufacture referred to herein. Thus, any disclosed process may be performed in any order that is practicable, including but not limited to simultaneous performance of one or more steps that are indicated as sequential.

Although the present invention has been described in connection with specific exemplary embodiments, various changes, substitutions, modifications and/or alterations apparent to those skilled in the art can be made to the disclosed novel lighting system without departing from the spirit and scope of the invention as set forth in the appended claims.

What is claimed is:

1. A composite lighting apparatus for inhibiting the optical imaging of subcutaneous veins comprising:
a first narrow light emitter; and
a second narrow light emitter;
wherein when the first narrow light emitter and the second narrow light emitter are energized a composite light is emitted that is characterized by a cyanosis observation index (COI) value of greater than four (4.0) and has a correlated color temperature (CCT) of between about 2000° K to about 50,000° K that is one of on the blackbody locus or near the blackbody locus.

2. The apparatus of claim 1, wherein the first narrow light emitter emits a blueish light.

3. The apparatus of claim 2, wherein the first narrow light emitter has a peak wavelength in the range of about four hundred forty nanometers (440 nm) to about four hundred and sixty nanometers (460 nm).

4. The apparatus of claim 1, wherein the second narrow light emitter emits a yellowish light.

5. The apparatus of claim 4, wherein the second narrow light emitter has a peak wavelength in the range of about five hundred and sixty nanometers (560 nm) to about five hundred and eighty-five nanometers (585 nm).

6. The apparatus of claim 1, wherein when the first and second narrow light emitters are energized the composite light that is emitted is characterized by a COI value of greater than 20.

7. The apparatus of claim 1, wherein when the first and second narrow light emitters are energized the composite light that is emitted is characterized by a COI in the range of about 21 to about 46.

8. The apparatus of claim 1, wherein at least one of the first and second narrow light-emitters comprises a light-emitting diode (LED), an organic light-emitting diode (OLED), a fluorescent lamp, a vapor discharge lamp, or an HID lamp.

9. A lamp which when energized inhibits the optical imaging of subcutaneous veins comprising:
at least two light-emitting elements having a combined light emission when energized; and
wherein when the at least two light-emitting elements are energized the lamp generates light exhibiting a correlated color temperature (CCT) of between about 2000 Kelvin (2000° K) to about 50,000° K, having a cyanosis observation index (COI) in the range of about 21 and 46, and having a CRI value of between about −13 and 41.

10. The lamp of claim 9, wherein at least one of the light-emitting elements comprises a light-emitting diode (LED), an organic light-emitting diode (OLED), a fluorescent lamp, a vapor discharge lamp, or an HID lamp.

11. A method for providing a lamp which when energized inhibits the optical imaging of subcutaneous veins comprising:
(a) identifying a target chromaticity point having a ccy value within +/−0.02 of the blackbody locus and having a (ccy, ccx) point lying within the CCT range of 2,000 degrees Kelvin (2,000° K) and 50,000° K;
(b) identifying a target cyanosis observation index (COI) value greater than 4.0 desired for the lamp;
(c) identifying a target CRI value desired for the lamp;
(d) choosing a plurality, “n,” of light sources having distinct emissions (ccxᵢ, ccyᵢ), where i=2 to n, such that the color triangle formed by at least one set of three (ccxᵢ, ccyᵢ) values contains the target chromaticity point or for that scenario where only two light sources having distinct emission are chosen, a line connecting their (ccxᵢ, ccyᵢ) values that includes the target (ccx, ccy);
(e) combining the light sources from step (d) in a ratio such that the target (ccx, ccy) value is obtained;
(f) calculating the COI using the AS/NZS 1680 standard;
(g) calculating the CCT from the ccx, ccy coordinates of the combined light sources from (d);
(h) calculating the CRI of the system;
(i) comparing the calculated COI to the target COI from step (b);
(j) comparing the calculated CRI to the target CRI from (c); and
(k) if the target values are not achieved, returning to step (d) and choosing additional or replacement light sources that satisfy the condition of step (d) and repeating steps (e)-(j) until the targets are met, or, if the target values are achieved, (l) constructing and measuring the illumination system to ensure compliance with the target values established in steps (a)-(c).

12. The method of claim 11 wherein the selected COI value of the lamp is in the range of about 21 to about 46.

13. The method of claim 11 wherein the selected CRI value of the lamp is in the range of about of about −13 and 41.

14. The method of claim 11 wherein at least one of the at least two light sources comprises a light-emitting diode (LED), an organic light-emitting diode (OLED), a fluorescent lamp, a vapor discharge lamp, or an HID lamp.
